(19) United States
(12) Patent Application Publication
(10) Pub. No.: US 2020/0023672 A1
(43) Pub. Date: Jan. 23, 2020

(54) METHOD FOR PRODUCING A CONTROL ELEMENT MADE OF PLASTIC WITH BACKLIT IMAGERY THAT IS METALLIZED ON ONE SIDE, CONTROL ELEMENT WITH BACKLIT IMAGERY, AND MACHINE FOR CARRYING OUT A PLURALITY OF METHOD STEPS

(71) Applicant: Kunststofftechnik Bernt GmbH, Kaufbeuren (DE)

(72) Inventors: Franz HUBER, Stöttwang (DE); Carsten BROCKMANN, Landsberg am Lech (DE)

(21) Appl. No.: 16/518,439

(22) Filed: Jul. 22, 2019

(30) Foreign Application Priority Data
Jul. 20, 2018 (DE) 10 2018 117 643.0

(51) Int. Cl. B44C 1/22; B44F 1/06; C23C 14/02; C25D 5/02; C25D 5/54; C25D 7/00

(52) U.S. Cl. CPC B44C 1/228; B44F 1/06; C23C 14/021; C08L 69/00; C25D 5/54; C25D 7/00; C25D 5/024

(57) ABSTRACT

A method for producing a control element made of plastic with backlit imagery that is metallized on one side, particularly for a motor vehicle, and a machine that is configured to carry out the aforementioned method, as well as to a control element with backlightable imagery.

### CROSS REFERENCE TO RELATED APPLICATIONS

This application is related to and claims the benefit of German Patent Application Number 10 2018 117 643.0 filed on Jul. 20, 2018, the contents of which are herein incorporated by reference in their entirety.

### TECHNICAL FIELD

The present disclosure relates to a method for producing a control element made of plastic with backlit imagery that is metallized on one side, particularly for use in motor vehicles, for example as a control element for onboard driver information systems or for activating onboard vehicle functions such as interior lighting, start/stop button, control elements of an air conditioner, switches for vehicle lighting, etc.

The present disclosure further relates to a control element that is by means of the method and to a machine for carrying out a plurality of method steps of the method according to the disclosure.

### BACKGROUND

Basically, two methods are known from the prior art for producing metallized control elements made of plastic. They are based either on the metallization of a control element made of a plastic by means of PVD (physical vapor deposition) method, or on the electroplating of a control element made of plastic by means of electrochemical methods. While both methods basically enable durable metal coatings to be applied to plastic control elements, it remains problematic to this day to metallize control elements by means of PVD methods such that the metal layer deposited on the plastic part has sufficient resistance to abrasion and corrosion even without an additional protective layer such as a transparent protective lacquer, for example. Also, plastic parts that are metallized by means of PVD methods do not have the oft-desired “cold touch” due to the small layer thicknesses of the applied metal layers, meaning that the haptics of the metallized plastic part do not correspond to those of a metal part.

DE 10 208 674 A1 discloses a method for producing plastic control elements that are galvanically metallized on one side. In particular, it describes a method for producing a control element that is galvanically metallized on the front side and has backlit symbols, wherein a base body made of a transparent or translucent plastic material is produced in a first step in the context of the disclosed method with a front side and a back side, with a region of the back side being covered or shielded in the subsequent method step in order to prevent a galvanic coating in this region. The base body is then electrically contacted with the covering or shield that is applied. Subsequently, the base body is chemically or, optionally, galvanically pretreated in order to produce a thin layer of metal outside of the covered region. This first metal layer is then partially removed in order to produce the symbol. Finally, the metallic surface coating is completed through electroplating. In the abovementioned patent application, it is proposed to either apply a protective lacquer to the metal layer for partial removal of the metal layer and subsequently etch off the areas of the metal layer that are not covered by the protective lacquer or, alternatively, to generate the symbol by means of laser ablation.

DE 10 2010 016 973 B4 discloses a manufacturing method for a plastic control element composed of a two-part plastic base body, with a sub-body that is arranged on the rear side being made of a non-electroplatable plastic A, and with an electroplatable layer of an electroplatable plastic B being arranged on the front side. The plastic base body is manufactured by injection molding. An electrically conductive first metal layer is then deposited on the electroplatable layer of the plastic base body by chemical or physical deposition. As a result, the first metal layer is patterned through partial ablation to form the imagery, and at least one second metal layer is subsequently deposited on the textured first metal layer through electrochemical deposition.

In these processes, the components are fed to an electroplating process and chemical-physical pretreatment after injection molding. The components must be removed from the electroplating process in order to perform texturizing, e.g., laser structuring. Then, the components treated in this manner are again fed to the electroplating process and the deposition is continued. This additional operation for texturizing the deposited metal surface increases production costs.

A galvanically decorated component is known from DE 20 2015 006 095 U1 that is manufactured by means of laser-activated transfer printing in conjunction with subsequent galvanic processing. After the injection-molding of a plastic body, a printed image is applied from a non-electroplatable lacquer to the plastic body. The printed image is transferred from a printed image that is imprinted on a carrier by applying heat to the component using a laser beam. One drawback of such an application is the relatively high energy consumption and comparatively high cost of such a printing machine.

A method for producing a control, decorative, or display element that can be electroplated on the front side is known from DE 10 2007 015 625 B4. In that method, in the case of an electroplatable base body, for example a plastic blank, a mask of non-electroplatable material providing an imagery is applied. This can be done by printing with a transparent or translucent lacquer. Alternatively, the imagery can be welded on. Following the printing process, metal is deposited on the non-printed regions by electroplating. This process may be preceded by pretreatment steps. In such a method, it is disadvantageous that the imprinted imagery often lacks a sharp contour in its edge regions. As a result, insufficient metal deposition can occur in these regions during the ensuing electroplating. On the one hand, this can lead to visual defects in the form of undesirably blurred material transitions and, on the other hand, to a chipping of the applied metal in the peripheral regions bordering the imagery.

### BRIEF SUMMARY

The present disclosure provides a method for producing a control element made of plastic that is metallized on one side and can be realized in a cost-effective manner on an industrial scale, allows for a continuous electroplating process, and ensures high product quality.

The disclosure also provides a control element with backlit imagery that is inexpensive to produce on an industrial scale, can be manufactured in a continuous electroplating process, and has a high product quality.

Furthermore, the disclosure provides a machine by means of which essential manufacturing steps of the claimed method can be carried out.

According to the disclosure, a method for producing a control element made of plastic with backlit imagery that is metallized on one side is proposed. Such control elements are installed in motor vehicles, for example. The method comprises the following method steps:
a. Producing a plastic base body with
   i. a sub-body made of a non-electroplatable plastic A that is arranged on the rear side and
   ii. an electroplatable layer of an electroplatable plastic B that is arranged on the front side,
b. applying a filler composition to at least a portion of the electroplatable layer;
c. forming the imagery through laser-lithographic processing of the applied filler composition in the regions forming the imagery;
d. removing filler composition outside of the imagery from the electroplatable layer;
e. depositing at least one metal layer on the electroplatable layer of the plastic base body through
   i. chemical deposition or
   ii. electrochemical deposition or
   iii. chemical or physical deposition of at least one electrically conductive metal layer and subsequent electrochemical deposition of at least one additional metal layer on the electrically conductive metal layer.

A control element with backlightable imagery, particularly for a motor vehicle, can thus be produced using the described method that comprises a plastic base body with a sub-body made of a non-electroplatable plastic A that is arranged on the rear side and an electroplatable layer of an electroplatable plastic B that is arranged on the front side, the imagery being formed by a filler composition that is applied to the electroplatable layer and processed by means of laser lithography, and at least one metal layer being deposited on the electroplatable layer. The control elements produced by means of the present method can also be used for other applications, including as a component of household and sanitary appliances, for example.

The filler composition can be cured through laser-lithographic processing of the applied filler composition in the regions forming the imagery. In the context of the present disclosure, a curing of the filler composition refers to a change in the flowability of the filler composition. As a rule, the filler composition will initially be in a flowable, i.e., liquid state when it is applied to the electroplatable layer. As a result of the subsequent laser-lithographic processing, the flowability of the filler composition that is applied to the electroplatable layer in the processed regions is reduced to such an extent that the contour of the printed symbols or imagery no longer changes in an optically perceptible manner at least for a period of at least one minute, preferably at least 10 minutes, and especially preferably at least one hour. Here, “optically perceptible” is intended to mean with the naked eye or at 10× magnification at most. If an optically perceptible change in the contour occurs after the stated period of time has lapsed, then while this is still to be regarded as “curing” for the purposes of the present disclosure, it will be referred to below as “partially cured.”

In the context of the present disclosure, curing of the filler composition preferably means that the flowability of the printed filler composition is reduced to virtually zero, i.e., that the contour of the applied filler composition, which has been processed by laser lithography, no longer changes even over observation periods ranging from several hours to days or months. This degree of curing is hereinafter referred to as “completely cured.”

Both the degree of curing termed “partially cured” and the degree of curing termed “completely cured” are included by the present disclosure.

After the application of the filler composition to at least a portion of the electroplatable layer, the filler composition is lithographically processed in the regions forming the imagery, preferably by means of laser lithography. As a result of the laser-lithographic processing, also called laser writing, the filler composition cures at least partially in the treated locations.

As a matter of principle, laser-lithographic processing can be carried out in two different ways, namely by processing a negative photoresist (negative filler composition) or a positive photoresist (positive filler composition). Before laser-lithographic processing, the filler composition that forms the negative or positive photoresist is applied to the electroplatable layer, for example over the entire surface. During laser-lithographic processing, the filler composition is partially irradiated by means of at least one focused laser beam of at least one laser. In the irradiated regions, the irradiation results in a local chemical or physicochemical alteration of the applied photoresist, particularly in terms of its local solubility or flowability. If the solubility is reduced locally by the irradiation, it is called a negative photoresist, whereas a local increase in solubility as a result of the irradiation is characteristic of positive photoresists. The present method is based on laser-lithographic patterning on a negative photoresist.

As an initial overview, the laser-lithographic processing of the filler composition that is applied over the entire surface of the electroplatable layer, for example, will be explained with reference to a simple example. Let us suppose that the imagery to be used concerns a simple numeral such as the numeral 5, for instance. In order to form the contours of the numeral 5, a laser beam emitted and focused by a laser device is moved relative to the surface of the filler composition in accordance with the shape or contour of the numeral 5. The surface of the filler composition can also be moved relative to a stationary laser beam.

The laser beam scans the surface of the filler composition in those regions forming the imagery—here, in the area in which the numeral 5 is to be written. During laser writing, the filler composition cures at least partially in the treated regions, here in the vicinity of the numeral 5. Consequently, the filler composition has a lower flowability or a higher strength than the filler composition surrounding the numeral.

In accordance with step d of the method according to the disclosure, the uncured filler composition is removed, for example by washing with a suitable solvent or by means of a subsequent pickling process as a precursor to the electroplating process. Removal by spraying with solid carbon dioxide, i.e., with dry ice, is also conceivable. In particular, spraying with dry ice pellets that are sprayed at high speed onto the surface to be cleaned can be considered. After removal of the uncured filler composition, the laser-lithographically cured region or imagery—in this case, the numeral 5—is raised in relation to the surrounding regions of the electroplatable layer. After the laser-lithographic processing according to step e of the method according to the disclosure, the electroplatable layer undergoes an electroplating process.

If the applied filler composition is only partially cured after the laser-lithographic processing, then a complete curing of the applied filler composition generally occurs in an additional method step downstream from step c. On the one hand, this can be achieved through active treatment of the laser-lithographically processed regions of the filler composition, for example with crosslinking radiation such as UV or X-ray radiation or through the introduction of heat. On the other hand, complete curing can be easily achieved through the passage of time—for example, by means of a crosslinking reaction that is already initiated by means of laser-lithographic processing but that progresses slowly in time compared to the duration of the sequence of method steps b and c. In the latter case—i.e., complete curing through the passage of time—the curing can occur parallel to the execution of method steps d and e. In that case, the lithographically processed regions cure during the removal of uncured filler composition or the execution of the electroplating process.

The method according to the disclosure reduces the likelihood of material damage to the plastic base body in the vicinity of the electroplatable layer, particularly in comparison with those methods which are known from the prior art, in which the imagery is formed subsequent to the electrodeposition of the metal by means of laser structuring, for example. After all, in the present method, the focus of the laser beam that is used during laser-lithographic processing or curing is primarily incident on the applied filler composition. In contrast, in the case of the laser structuring that is known from the prior art, the laser focus can also be directly incident on the plastic material and damage the structure thereof as a result of uninterrupted layer ablation after the removal of the layers directly on the plastic base body. Roughened or structured surfaces (e.g., brush structures) of the plastic base body can be damaged in the process, for instance. Such structures can be shaped during injection molding against the plastic base body.

At least method steps b and c of the method described at the outset are preferably carried out in a machine that is likewise the object of the disclosure. The machine comprises at least one station for applying a filler composition to at least a portion of the electroplatable layer and one station for forming the imagery through laser-lithographic processing of the applied filler composition in the regions forming the imagery. The machine can also have an additional station in which the filler compound located outside of the imagery is removed from the electroplatable layer. The machine can also include a secondary curing station for final curing of the regions of the filler composition forming the imagery. The implementation of a plurality of method steps in one and the same machine reduces process costs and increases production economy. The implementation of a plurality of steps in a common machine also reduces the space requirement in the production facility.

The method on which the present disclosure is based is less expensive than those methods of production which are known from the prior art for control elements made of plastic that are metallized on one side and have backlightable imagery. The cost advantages result from the fact that, in the method according to the disclosure, no additional laser processing step need take place for the purpose of structuring between the electrochemical metal deposition or electroplating. Accordingly, the electroplating can take place continuously. In other words, the electroplating does not have to be interrupted in order to introduce the imagery. With regard to the teaching of DE 20 2015 006 095 U1, the cost advantages are achieved particularly through the use of a simplified application and curing system for the filler composition. Moreover, by virtue of the defined formation of the contours of the imagery by means of laser-lithographic processing and the sharply defined edges of the imagery associated therewith, the method according to the disclosure makes it possible for metal to be galvanically deposited in a reliable manner even in the edge regions of the formed imagery. This results in a sharp material transition between the imagery and the galvanically applied metal layers.

With the proposed method, at least one metal layer, particularly an electrically conductive metal layer, can first be chemically deposited on the electroplatable layer of the plastic base body in order to subsequently perform conventional electrochemical galvanization for the purpose of depositing at least one additional metal layer on the electrically conductive metal layer (method step e, variant iii). Alternatively, the proposed method makes it possible for at least one metal layer to be deposited directly on the electroplatable layer by means of electrochemical galvanization (method step e, variant ii)—i.e., without having already chemically deposited one or more metal layer(s) beforehand. The exclusively chemical deposition of at least one metal layer on the electroplatable layer is also conceivable with the proposed manufacturing method (method step e, variant i).

In the context of the method on which the disclosure is based, the plastic base body is preferably produced by means of injection molding, in which case a non-electroplatable plastic A is injected against an electroplatable plastic B. Conversely, the electroplatable plastic B can also be injected against the non-electroplatable plastic A.

During injection molding , a material such as one of the plastics A or B is liquefied—e.g., melted—in an injection-molding machine and injected into a mold under pressure. Multicomponent systems—e.g., mixtures of different plastics—can also be processed using the injection-molding process. The interior of the mold determines the shape and the surface structure of the injection-molded component, such as a sub-body of the plastic base body, for example.

In particular, the size dimensions of the interior space and/or surface structures provided on the inner surfaces of the mold—e.g., projections or recesses—define the shape and surface structure of the injection-molded component. Also, objects or components such as a sub-body of the body, for example, can be arranged in the mold before the actual injection molding in order to inject another plastic against this sub-body. This enables the components that are arranged in the mold—e.g., a first sub-body—to codetermine the shape of the cavity during injection molding, meaning that they, like the mold itself, impart shape to the injection-molded component. Objects that are additionally arranged in the mold can also codetermine the shape of the injection-molded component, but the objects can form a common composite component with the injected plastic composition.

In order to inject a plastic against an already-cured component, for example a sub-body, a molten plastic composition is conducted via a runner system to the cavity of the mold. This is then cast against the component—e.g., the abovementioned sub-body—that is arranged in the mold. Various runner systems are known.

The choice of the runner system has a direct impact on the quality of the injection-molded component—in this case of the plastic base body. Particularly the shape of the component to be manufactured must be taken into account in selecting the runner system. For rotationally symmetrical components, for example, a diaphragm gate is suitable. Other relevant runner systems include the pin gate, sprue gate, tunnel gate, or film gate.

In the mold, the plastic composition that is injected against the sub-body cools and/or cross-links and thus passes into a solid state, or cures. Thereafter, the plastic base body can be removed from the mold.

Taking these parameters into account which determine the injection molding process, the plastic base body can be manufactured in different ways. According to a first variant, a non-electroplatable sub-body is produced from a non-electroplatable plastic A, and an electroplatable layer of an electroplatable plastic B is applied to the front side of the sub-body by means of injection molding. According to a second variant, said production sequence for the plastic base body is reversed, so that the non-electroplatable plastic A is injected against a sub-body made of electroplatable plastic B or against the electroplatable layer.

A plastic base body that is produced in this manner can be a so-called 2K component. Such components can be made from two different plastic components according to the previously described injection molding process. Preferably, such a sequence is maintained during the manufacture of the two components of the base body, with the plastic component being injected first whose plastic material must be processed at a higher temperature, i.e., that has the higher melting point, and with the second plastic component that is to be processed at a lower temperature being injected in a subsequent method step against the preferably already solidified first plastic component.

Moreover, the injection-molding process that is known as the injection molding decoration (IMD) method has also proven to be suitable for producing the plastic base body that is to be used according to the disclosure. In the context of such an IMD process, a film made of an electroplatable plastic B is placed in an injection mold and subsequently back-injected with a non-electroplatable plastic A. Depending on the shape of the main body or the material properties of the film, it is also conceivable to insert a non-electroplatable plastic A film into an injection mold in order to form the non-electroplatable back of the base body and to back-inject this with an electroplatable plastic B, in which case the component that is composed of an electroplatable plastic B forms the electroplatable surface of the base body in the finished base body. The latter variant of the method has the advantage that it is the surface of an injection-molded plastic part that is to be metallized, for which considerably more empirical figures available in the prior art than for the metallization of plastic films.

After the production of the plastic base body, a filler composition is applied to at least a portion of the electroplatable layer thereof. According to an advantageous embodiment of the method, a non-electroplatable filler composition is used. The filler composition can be a material for which radiation can be used to induce curing, for example. According to the disclosure, the radiation is introduced by means of a laser beam focused on the filler composition by means of laser-lithographic processing—i.e., laser writing. The radiation introduced can initiate a radiation-induced crosslinking reaction of the filler composition. The radiation is preferably a radiation that initiates the crosslinking reaction, such as UV radiation, infrared radiation, or X-ray radiation. Radiation from other wavelength ranges can also be used within the scope of the disclosure for laser-lithographic processing, provided that the radiation is suitable for activating a crosslinking reaction. Preferably, the filler composition comprises at least one polymer component. Alternatively or in addition, the filler composition may be thermally curable. Through laser-lithographic processing, the introduction of radiation by the laser can also be accompanied by a heat input. Also as an alternative or in addition, the filler composition can be cured through evaporation of a solvent, i.e., by means of a drying process. This process can be promoted by an external heat input, whether it be in the course of laser-lithographic processing or by means of an additional unit for emitting heat radiation. Suitable solvents that can be employed include water or an organic solvent, for example.

Preferably, the filler composition is curable under the action of radiation, particularly UV radiation or X-ray radiation, with the radiation being preferably being emitted in the context of the disclosure by a laser—e.g., a UV laser—in the direction of the filler composition. Structures are formed by the laser-lithographic processing that are raised in relation to the surface of the electroplatable layer, particularly after removal of the filler composition outside of the imagery in step d of the method according to the disclosure.

In the case of radiation-induced curing by means of laser-lithographic processing, it is also possible to use a mask that is arranged above the filler composition to be irradiated and allows laser radiation to pass through in the direction of the filler composition in a selective manner, i.e., only in certain regions. For example, the mask can consist of a material that is impermeable to laser radiation and have openings for the defined passage of the laser radiation. The openings can correspond to the imagery to be formed. However, such mask-based laser lithography is not the method of direct laser writing that was explained at the outset.

The curing process can also involve chemical crosslinking that is induced or activated by the incident laser radiation, such as the UV radiation of a UV laser or X-ray radiation—e.g., synchrotron radiation. If the filler composition comprises a solvent, this can evaporate as a result of the heat input associated with the irradiation. The curing process then amounts to a conventional drying process. By virtue of the fact that the filler composition used is non-electroplatable, metal is prevented from depositing on the laser-lithographically formed structures in subsequent method steps, particularly during the electrochemical or galvanic treatment of the plastic base body. The laser-lithographically processed regions and the formed imagery are galvanically stable.

According to another advantageous embodiment of the disclosure, a filler composition is used which comprises a resist that can cure under UV irradiation, for example a transparent or colored photoresist. Due to the weak absorption of the laser radiation, using a transparent resist can result in multiple curing caused by multiple scattering. This is undesirable because it can lead to inhomogeneities of the degree of curing in the treated regions. The curing can lead to hardening in the lateral direction—i.e., in the direction substantially perpendicular to the laser beam—that reaches beyond the laser focus by more than 100-200 μm. Through the use of a colored resist with a stronger absorption of the laser radiation, such multiple scattering is prevented along with the associated undesired multiple curing. The curing is limited substantially to the laser focus.

Furthermore, particles can be added to the resist that are suitable for absorbing laser beams. This, too, can prevent multiple scattering. In addition to the abovementioned constituents, the filler composition can also comprise additional components such as binders, UV monomers, photoinitiators, defoamers, thickeners, dispersing additives, or fillers, for example.

The use of resists is advantageous because it allows for a variety of color and property variations. The addition of particles that absorb laser radiation facilitates the process of the laser-lithographic treatment of the filler composition, or laser writing. After all, due to the radiation absorption on the part of the added particles, the energy can be efficiently transferred to the filler composition, whereby an additional heat input is ensured which promotes curing.

According to an advantageous embodiment of the disclosure, the filler composition is applied over the entire surface of the electroplated layer. A full-surface application is technically easier and less expensive to implement, as opposed to a region-by-region or selective application of the filler composition. Corresponding masks for applying the filler composition can thus be dispensed with. This can mean cost and time advantages, particularly when large numbers of control elements are being produced.

Similarly, the disclosure of the disclosure does not preclude applying the filler composition to those portions of the electroplatable layer in which the imagery is formed. In particular, the filler composition can be selectively applied in a desired subregion of the electroplatable layer using an applied mask. The applied mask can have openings into which the filler compound is introduced. After the removal of the applied mask, the coating composition is located in the desired position and can undergo laser-lithographic processing. This variant offers advantages from an ecological perspective and in terms of material costs. To wit, in contrast to a full-surface application of a filler composition to the electroplatable layer, quantitative savings are achieved in the case of partial application. Thus, on the one hand, less filler composition is needed, which brings about an immediate reduction in material costs, and on the other hand it is possible to dispense with any recirculation or recycling steps.

According to another advantageous embodiment of the disclosure, the filler composition can be printed, sprayed, rolled, or painted on the electroplatable layer.

The possible printing processes include gravure, letterpress, flat, and gravure printing in the categories intaglio printing, photogravure, letterset printing, pad printing, flexographic printing, letterpress printing, embossing, offset printing, Toray printing, and screen printing. Application by means of digital printing processes is also possible. These include inkjet printing, 3D printing, electrophotography, laser sublimation printing, dye sublimation printing, laser ablation, and other methods, to name just a few of the most important ones.

During spraying, the filler composition can be sprayed through one or more nozzles under pressure in the direction of the electroplatable layer. The methods of rolling or brushing are particularly suitable for the full-surface application of the filler composition to the electroplated layer.

Alternatively, the filler composition can be applied to the electroplatable layer by submerging the electroplatable layer into a receiver vessel filled with the filler composition. Such a process represents a conventional dipping technique. This can be carried out quickly, but sufficient adhesion of the filler composition to the substrate—in this case the electroplatable layer—must be ensured. The adhesive power can be increased through pretreatment of the electroplatable layer, for example by roughening or thermal pretreatment.

According to another embodiment of the disclosure, the laser-lithographic processing can be carried out with a pulsed laser, preferably with an Nd:YAG, a CO₂, or a UV laser. Preferably, a laser is used whose wavelength is adapted to the wavelength necessary for initiating a photopolymerization of the filler composition. If it is a filler composition that is able to undergo photopolymerization through the introduction of UV radiation, the use of a UV laser is particularly suitable.

It can also be advantageous for the radiation emanating from the laser to experience high absorption in the filler composition, whereas the absorption in the plastic A and plastic B is low. This prevents plastic material of the plastics A or B from being destroyed during the lithographic treatment of the filler composition. Due to the low absorption in the plastics A and B, a material-damaging influence during laser writing is at least reduced.

During the laser-lithographic processing of the filler composition according to step c of the method on which the disclosure is based, a focused laser beam of the laser is guided over the filler composition along a predetermined travel path. For this purpose, the laser can be connected to a holding device with a drive and displacement unit that enables the laser to be displaced along the predetermined travel path. The travel path can correspond to the contour or shape of the imagery to be formed. The travel path can be repeated multiple times and/or consist of a plurality of successive traversing movements. The laser-lithographic processing can be carried out simultaneously by a plurality of lasers.

This can be advantageous particularly if the imagery consists of several individual symbols. Then each laser symbol can be assigned to each individual symbol to be lithographically structured. Laser-lithographic processing enables ultrafine structures to be formed, so that reworking of the formed structures can also be dispensed with, depending on the customer's requirement. However, this represents only an optional variant. After all, even ultrafine structures can undergo secondary processing—e.g., laser finishing—in order to form sharp edges.

Similarly, the plastic base body can be moved with the filler composition applied to the electroplatable layer relative to a positionally fixed-focus laser beam during laser-lithographic processing. This, too, can be used to structure the imagery. In that case, the plastic base body must be arranged on a movable positioning unit. This can be configured in the form of a multiaxial linear unit, for example.

The filler composition can cure at least partially at the treated locations by means of laser processing or laser-lithographic processing. In the event of incomplete (i.e., partial) curing, the filler composition can undergo a secondary curing process after the laser processing in which the curing is completed. The secondary curing process can be promoted simply by the passage of time or through additional heat or radiation input. However, it is also possible within the scope of the disclosure for the filler composition to be completely cured by means of laser processing at the treated points.

The secondary curing can be achieved by means of a secondary curing station downstream from step c of the method according to the disclosure—i.e., laser-lithographic processing. Likewise, the secondary curing station can be arranged downstream from step d of the method according to the disclosure—i.e., the removal of the excess filler composition. If the filler composition is not completely cured by the laser-lithographic processing, the partially cured filler composition can be post-cured during the transporting of the component to a subsequent processing step. The resists used in the framework of the method according to the disclosure can be caused to dry or cure through the inputting of radiation, e.g., UV radiation. In said secondary curing station, the components can be irradiated with UV light. The irradiation with UV light takes place here preferably by means of mercury vapor lamps or LED lamps. The UV radiation can be applied by means of a suitable irradiation device. The irradiation device can be integrated into a superordinate machine.

As mentioned at the outset, the filler composition that is outside of the imagery or not cured is removed from the electroplatable layer. This can be done, for example, with the aid of a suitable solvent, i.e., in the manner of a washing-off. Suitable solvents are any solvents by means of which the filler composition can be removed from the electroplatable layer. The filler composition must therefore have at least partial solubility in the selected solvent. Aqueous or organic solvents can be considered as a matter of principle. Fluids such as CO₂ or supercritical CO₂ are also suitable solvents. For example, the filler composition can be removed using a CO₂ spray system. Removal using solid carbon dioxide in the form of dry ice—e.g., dry ice pellets—is also possible. The dry ice pellets are sprayed or blown at high speed onto the surface to be cleaned, here in the direction of the uncured filler composition. As a result, the filler composition can solidify, become brittle, and eventually flake off or be removed mechanically.

Alternatively, the filler composition can be removed by pickling with a mordant, for example an oxidizing solution such as chromosulfuric acid or potassium permanganate. In principle, organic or inorganic acids and lyes can be employed as mordants. The selection depends on the solubility or ablation efficiency of the mordant with respect to the filler composition used. In addition, the mordant must not be too aggressive toward the electroplated layer or the plastic base body. While it is true that the mordant that is used in a pretreatment step for electroplating can similarly be used to remove the filler composition in any event—this offers cost advantages, in particular—the electroplatable layer or the plastic base body must not suffer excessive damage.

Furthermore, advantages can be attained in the context of the disclosure if the edges of the laser-lithographically processed bodies are reworked after complete or partial curing thereof with another laser in order to impart a sharp contour to the imagery. After the laser writing of the imagery, the filler composition begins to cure in the treated regions or is already completely or at least partially cured as a result of the laser writing or laser-lithographic processing. In the edge regions of the imagery, the edges can be reworked with at least one laser, for example by moving the at least one laser along the edge regions of the laser-lithographically written imagery. In this way, the edges of the imagery are scanned and reworked by the at least one laser or laser beam.

The contours or edge regions of the formed imagery can thus be sharpened or reworked through the laser input, for example through ablation or burning away of uncured or cured and/or excess filler composition. During laser finishing, the edges of the applied imagery are sharpened and irregularities eliminated or corrected. A laser beam or a plurality of laser beams can be moved over the component to be treated along a predetermined travel path—i.e., the electroplatable layer—and remove material projecting beyond the desired contour of the imagery. It is also possible to position the laser(s) in a fixed position and to move the component to be finished relative to the positionally fixed laser or to the positionally fixed lasers. Such secondary processing can be carried out immediately after method step c or method step d of the method according to the disclosure. A laser machining operation for sharpening the edge regions that is carried out simultaneously with the laser-lithographic treatment is also conceivable, for example by moving a laser beam associated with the laser-lithographic processing and a laser beam associated with the laser finishing successively along a predetermined travel path, or by moving the plastic base body relative to the laser beams.

It can be advantageous to carry out steps b and c of the method according to the disclosure in a machine that is provided with a plurality of stations, in which case method steps b and c are each associated with a station. The machine can have another station in which step d of the method is carried out. Preferably, method step b. is associated with a first station whereas method step c is associated with a second station. Method step d is then preferably associated with a third station of the machine.

The aforementioned machine can be a turntable machine, thus enabling at least method steps b, c, and optionally d to be carried out therewith. The machine can comprise an additional station in which the curing of the filler composition occurs.

According to the method according to the disclosure, at least one metal layer can be deposited on the electroplatable layer. The at least one metal layer can be a metal layer that is applied to the electroplatable layer by means of chemical deposition. Alternatively, at least one metal layer can be deposited on the electroplated layer directly by electrochemical means. However, it is advantageous to first chemically apply an electrically conductive metal layer to the electroplatable layer and then to deposit at least one additional metal layer on this layer through electroplating.

“Chemical deposition” is to be understood as an electroless, i.e., non-electrochemical deposition of a metal layer to the electroplatable layer.

For the sake of example, the deposition of a nickel layer from an electrolyte solution by means of a colloidal method will be described below.

In a first step of such a colloidal process, a layer of palladium seeds is applied to or deposited on the electroplatable layer from an electrolyte solution. Preferably, however, this occurs only on those regions surrounding the laser-lithographically processed regions of the plastic base body.

It is preferred that no material layer of palladium seeds be applied to the laser-lithographically processed regions of the filler composition. The application of the palladium seeds is often referred to as “activating the surface” of the component to be electroplated. Reference is made in this regard to the disclosure of DE 102 08 674 A1. It is known from the prior art, for example, that in order to activate the surface of the base body, palladium seeds can be applied from a colloidal solution to the electroplatable layer, it being possible for these applied palladium seeds to be protected by a protective tin colloid layer. It has proven expedient if, prior to the subsequent application of the metal layer to the activated, electroplatable layer, a protective tin colloid layer that optionally covers the palladium seeds is removed. This process, which is also referred to as “stripping,” can be carried out by washing the activated electroplatable surface of the base body, for example.

Subsequently, at least one metal layer, preferably nickel or copper, can be deposited on the activated surface of the main body of the control element in a suitable metal bath (i.e., in an electroless manner) in a suitable metal bath (so-called “chemical nickel” or “chemical copper”). Since the regions provided with the filler composition are not activated, no metal or only small amounts of metal are deposited thereon, which, however, can be removed in a subsequent step without much effort. Such chemical deposition can be followed by finishing with a resist. The chemical deposition can also be downstream from an electroplating process.

It can be advantageous to deposit a thin intermediate layer before the chemical deposition of the metal layer by means of a physical process, for example by means of PVD (“physical vapor deposition”).

If a nickel or a copper layer is chemically deposited, it typically has a layer thickness of between 100 nanometers and 5 micrometers, preferably between 500 nanometers and two micrometers, and especially preferably of about 1 micrometer. The minimum layer thickness is essentially dependent on the layer thickness at which sufficient electrical conductivity of the metal layer is achieved. The minimum layer thickness also determines the current-carrying capacity of the electrically conductive metal layer that is required for the subsequent electroplating steps, if such a process is subsequently provided for. The maximum layer thickness is primarily determined prior to the rate of deposition of the chemical or physical process being used to electrolessly deposit the electrically conductive metal layer. If the residence time in the corresponding method step is too long, the entire process becomes uneconomical.

Preferably, at least the method steps “activation of the surface,” “application of the electrically conductive metal layer (chemical nickel/chemical copper)” are carried out in less than 24 h in order to prevent passivation of the reactive surface of the chemical nickel/chemical copper.

If the electrolessly deposited electrically conductive metal layer does in fact have only a low current-carrying capacity, which would be disadvantageous for subsequent electrochemical method steps, a first metal layer, for example of copper or nickel, can be optionally deposited by galvanic means on the electrically conductive metal layer in the case of low currents (so-called “copper precursor” or “nickel precursor”).

To complete the metallized control element, the thickness of the metal layer, which is possibly still covered with a thin layer of precursor or nickel, can be subsequently increased by means of a galvanic, i.e., electrochemical, process. As a rule, a first intermediate layer of copper is deposited for this purpose on the (electrically conductive) metal layer which, due to its high ductility, forms a bridge between the plastic base body, which has a high elasticity, and a decorative layer of a hard decorative metal such as chromium or also nickel that is deposited on the surface of the control element in a subsequent process step. This first intermediate layer of copper can have a layer thickness of 10 to 40 micrometers and above. As a rule, the electroplating process for depositing the first intermediate layer of copper is adjusted such that a layer thickness of this first intermediate layer of at least 20 micrometers is ensured on all control elements that are coated at the same time in the electroplating bath. The electroplating process—and hence metal deposition—does not take place in the regions of the plastic base body that are imprinted with the filler composition.

A second intermediate metal layer is oftentimes deposited on the first intermediate layer of copper in order to increase the corrosion resistance of the metal coating. This second intermediate layer can also increase the adhesion of the decorative layer that is applied to the surface of the control element to the first intermediate layer. Finally, the appearance of the decorative layer can be selectively influenced through suitable selection of the material of the second intermediate layer. The application of a second intermediate layer of nickel has proven to be especially advantageous. In that case, this second intermediate layer can be particularly composed of cracked nickel, matte nickel, semi-bright nickel, or bright nickel and, in turn, be subdivided again into intermediate layers. In the case of control elements that are subjected to especially strong mechanical loads, such as the gearshift knob of a gearshift lever of a transmission, for example, or of control elements that especially high exposure to the attack of corrosive media such as hand sweat, a layered structure that has proven advantageous consists of a layer of semi-bright nickel that is applied to the first intermediate layer and a layer of matte nickel that is deposited on the surface thereof and on whose surface a layer of cracked nickel is finally applied. The cracked-nickel layer contributes to a substantial increase in the corrosion resistance of the entire layered structure, which is considered to be the result of a controlled corrosive attack on the cracked nickel layer. Nonetheless, the adhesion of the decorative layer is also enhanced once again by this intermediate layer. The layer thickness of the second intermediate layer is typically between 5 and 30 micrometers, preferably 10 micrometers and above, in particular with a second intermediate layer of nickel.

A layer of a decorative metal, which can be chromium or nickel, for example, is subsequently deposited on the first intermediate layer of copper or on the optional second intermediate layer of nickel. Here, recourse is had to the inherently known processes for the formation of a semi-bright or matte nickel layer (aluminum design), a cracked-nickel layer, or a bright chromium layer. Typical layer thicknesses of this decorative layer are between 100 nanometers and a few micrometers, and preferably at least 300 nanometers in the case of chromium.

The layer thickness of the filler composition providing the imagery can advantageously correspond to the layer thickness of the at least one deposited metal layer. This enables the formation of a flat surface.

Finally, the metallized surface of the control element can be additionally provided with a suitable protective and/or decorative coat that is applied to the decorative layer composed of the decorative metal, such as chromium, for example, and further increases the corrosion resistance of the overall layered structure that is applied to the control element.

With the electroplating process described above, at least one metal layer can also be deposited directly on the electroplatable layer of the plastic base body (method step e, variant ii). This is possible insofar as the electroplatable layer is electrically conductive. A metallic primer or the use of an electrically conductive plastic is conceivable, for example. The plastic base body can also contain an additional metal component as an electroplatable layer, for example a metal foil against which the plastic B is injected.

According to another advantageous embodiment of the method on which the disclosure is based, the plastic B—i.e., the plastic providing the electroplatable layer—is a transparent or translucent polyamide, ABS, or an ABS/polycarbonate blend. The acronym ABS stands for acrylonitrile-butadiene-styrene copolymers. The plastic A is preferably a polycarbonate. If the base body is composed of sub-bodies of these materials, then a heavy-duty mechanical connection of the sub-bodies is ensured. A base body with especially high mechanical stability is obtained if the electroplatable layer is composed of an ABS/polycarbonate blend and the rear sub-body is made of polycarbonate. If the electroplatable layer is composed of polyamide, it can be advantageous to provide the electroplatable layer with a suitable structuring that causes additional engagement with the rear sub-body.

According to another advantageous embodiment of the disclosure, it can be advantageous for the surface of the electroplating layer to be electroplated to be roughened, for example by chemical treatment, before the deposition of the first metal layer. If the electroplatable layer is composed of ABS or ABS/polycarbonate blends, then the roughness of the surface can be increased by at least partially eluting the butadiene fractions of the ABS plastic out of the surface of the electroplatable layer. The treatment of the electroplatable layer or of the base body by means of a pickling process in a chromosulfuric acid bath can be suitable for this purpose. In the case of an electroplatable layer that is composed of polyamide, on the other hand, the surface roughness can be increased by chemically treating the electroplatable layer or the base body in such a way that the layer composed of polyamide swells up at least partially.

For further details on the electroplating process and on the combined chemical deposition and electroplating process, reference is additionally made to the disclosure of DE 10 2010 016 973 B4.

In addition, it should be noted that terms such as “comprising,” “having,” or “with” do not exclude other features or steps. Furthermore, the terms “a(n)” or “the” indicating a number of steps or features do not exclude a plurality of features or steps, and vice versa.

### BRIEF DESCRIPTION OF THE DRAWINGS

An advantageous embodiment of the method according to the disclosure will be explained in more detail in the following with reference to the accompanying drawing, in which

FIG. 1 shows a schematic illustration of the process flow of the method according to the disclosure;

FIGS. 2a-d show a schematic illustration of method steps c and d according to a first embodiment of the method on which the disclosure is based; and

FIGS. 3a-c show a schematic illustration of method steps c and d in a second embodiment according to the method on which the disclosure is based.

### DETAILED DESCRIPTION

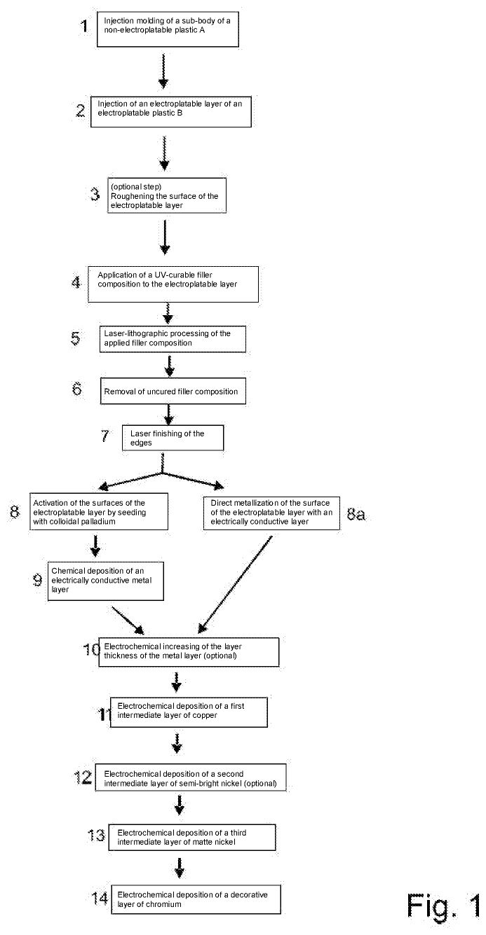

As shown in the schematic process diagram of FIG. 1, a sub-body made of a non-electroplatable plastic A (polycarbonate, for example) is produced in method step 1 by means of injection molding in an injection mold. The shape of the cast plastic is essentially defined by the mold, more particularly the cavity. In addition, other components can be placed into the mold against which the plastic composition A is cast.

In method step 2, an electroplatable layer of an electroplatable plastic B (e.g., ABS/polycarbonate blend) is injection-molded against the front side of this sub-body, whereby the base body of the control element according to the disclosure is formed as a two-component (2K) component. Method steps 1 and 2 can also be carried out in reverse order.

In the subsequent optional method step 3, at least the surface of the electroplatable layer of the control element undergoes a pickling process in which the butadiene fractions are eluted out of the surface of the ABS plastic part. This process step is preferably carried out in a chromosulfuric acid bath. Besides roughening the electroplatable surface of the plastic control element, contaminants, among other things, are removed from the electroplatable surface, particularly any adhered organic contaminants. This method step can be repeated after method step 5 or, in principle, represent method step 6.

According to method step 4, a filler composition is applied to the electroplatable layer of the plastic base body. The filler composition can be applied by imprinting, brushing, rolling, spraying, or by means of a dipping technique. The filler composition can be a paint, e.g., a UV paint, that comprises additional components such as particles for absorbing laser beams, for example.

In the illustrated method step 5, the imagery is formed, namely by laser-lithographic processing—also called laser writing. In the regions forming the imagery, i.e., those areas in which certain symbols are to be provided, a laser beam (preferably a UV laser) is moved over the filler composition along a predetermined path. In this case, the filler composition can cure completely or to a large degree. The laser can initiate photopolymerization in the filler composition and/or accelerate the curing through heat input, for example. After (partial) curing, uncured filler composition is removed according to method step 7, for example by washing or a pickling process.

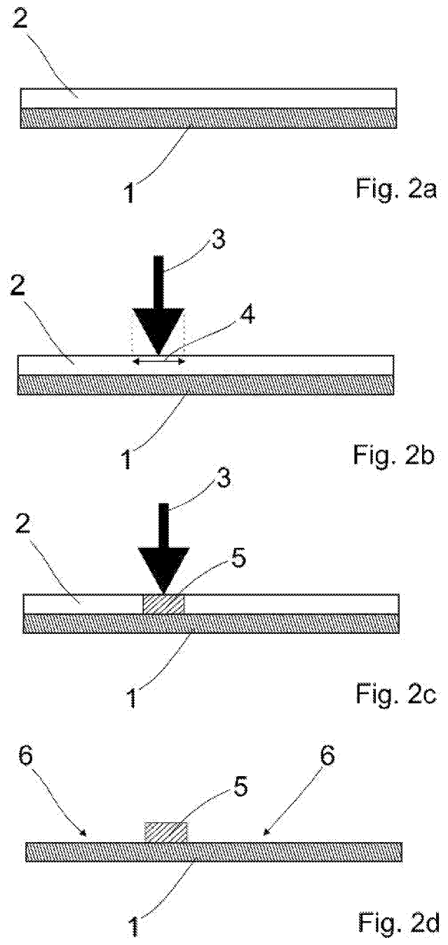

For the sake of example, FIGS. 2a to 2d show the process of laser writing and the removal of the uncured filler composition. As illustrated in FIG. 2a, a filler composition 2 has been applied to the electroplatable layer 1 prior to laser-lithographic processing. In the present example, the electroplatable layer 1 is coated over its entire surface with the filler composition 2. In those regions of the filler composition 2 in which the imagery is to be formed, a laser beam 3 is moved over the filler composition 2 along a predetermined path (FIG. 2b). In the lateral direction, a region of the filler composition 2 corresponding to a writing width 4 of the laser beam 3 is exposed by means of the laser beam 3 to the laser radiation 3 or processed by the laser. The laser beam 3 can be moved multiple times along the same path. If the focus of the laser beam 3 is smaller than the desired writing width 4, then the laser beam 3 can be moved multiple times along mutually parallel paths in the lateral direction. As a result of the action of the laser beams 3, the filler composition 2 cures at least in the region of the writing width 4 of the laser and forms a cured region 5. After the uncured filler composition 2 has been removed, the cured region 5 remains on the electroplatable layer 1 and is raised in relation to the regions 6 that have been washed out or freed of filler composition 2 (FIG. 2d). The cured region 5 thus forms the imagery.

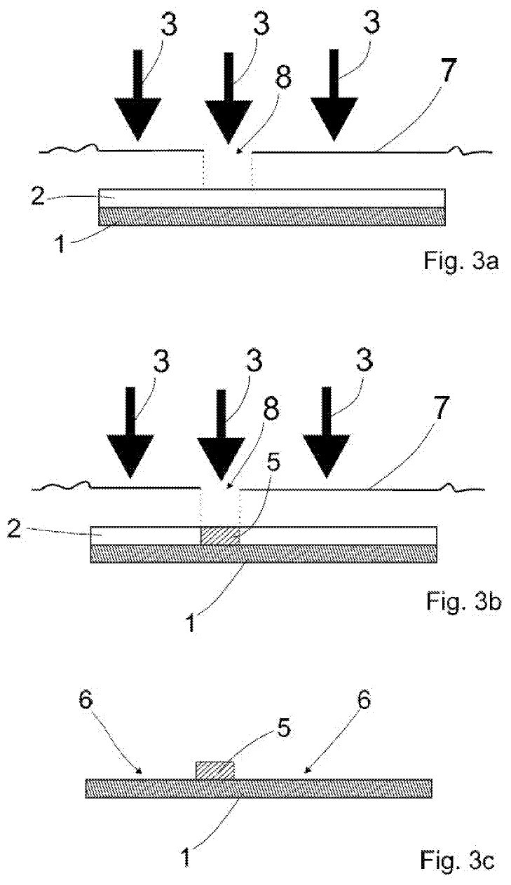

FIGS. 3a to 3c show a process that has been slightly modified in comparison to the process illustrated in FIGS. 2a to 2d. Instead of direct laser writing, the cured region 5 of the filler composition 2 (see FIG. 3b) is formed with the aid of a mask 7. The mask 7 is composed of a material that is impenetrable to the laser beams 3. As shown, however, the mask 7 has at least one opening 8 through which laser radiation 3 can pass in the direction of the filler composition 2. No positionally precise displacement of the laser beams 3 is required in this variant. However, in addition to the uncured filler composition 2, the mask 7 must also be removed from the substrate after the laser treatment. As shown in FIG. 3c, after the mask 7 is removed, imagery or a cured region 5 remains that is raised with respect to the regions 6 that have been washed out or freed of the filler composition 2.

After the laser-lithographic curing, a secondary curing process can take place.

Returning to the schematic process diagram of FIG. 1, the edges surrounding the imagery can undergo secondary processing in a method step 7 with one or more lasers in order to form clear outlines of the imagery. Excess filler composition is removed or lasered away.

In method step 8, the electroplatable surface of the base body is activated, i.e., the surface is seeded in a manner known from the prior art with palladium seeds from colloidal solution, the palladium seeds preferably being covered by a protective tin colloid. The protective tin colloid is removed by washing to form a surface with active palladium.

In method step 9, an electrically conductive first metal layer is applied to the activated surface of the base body by chemical means, i.e., without the use of an electroplating current. For this purpose, the base body is introduced into a suitable nickel bath, from which nickel is deposited on the activated surface of the base body (so-called “chemical nickel”). The resulting thin nickel layer has a thickness of about one micrometer. The nickel layer represents the (first) deposited metal layer.

In an alternative variant of the method, the electroplatable surface of the base body is activated in method step 8a—that is, the surface is seeded with palladium seeds from colloidal solution, the palladium seeds preferably being covered by a protective tin colloid. This is replaced by copper in an alkaline solution in a method step that is not shown. The resulting copper layer offers a sufficiently high coverage and thus electrical conductivity in order to be electrochemically galvanized without additional intermediate steps (such as the deposition of chemical nickel/chemical copper, for example). This procedure is also referred to as direct metallization.

Furthermore, it is known that the sequence of the method steps that are not shown in the figure—sourcing the plastic (ABS, ABS-PC, PC, PES, PEI, PEEK, etc.), pickling in an oxidizing solution (chromosulfuric acid, potassium permanganate, etc.), activation in a metal complex-containing solution, crosslinking by forming metal sulfides in an alkaline sulfide solution and, finally, electrochemical plating in a metal bath—makes it possible to dispense with a time-consuming electroless deposition of chemical nickel or chemical copper.

In optional method step 10, the layer thickness of the thin nickel layer is increased by several 100 nanometers through electrochemical deposition of nickel or copper at low current in order to increase the conductivity and/or current-carrying capacity of the first metal layer (“nickel precursor,” “copper precursor”).

In the next method step (not shown), the base body that is covered on the electroplatable surface with the first metal layer (i.e., a thin nickel layer and, optionally, a layer of nickel precursor or copper precursor) is removed from the electroplating process, washed, and dried.

The base bodies are then fed to the electroplating process. Here, in the next method step 11, a first metallic intermediate layer is electrodeposited in a first (or, if copper precursor or nickel precursor was applied: second) electrochemical electroplating step. This is usually made of copper and has a thickness of typically between 10 and 40 micrometers. This electroplating step is preferably carried out in such a way that a minimum layer thickness of the first copper intermediate layer of 20 micrometers is achieved regardless of the position of a control element on the holder.

In the subsequent method steps 12 and 13, a second intermediate layer of nickel is electrodeposited on the first intermediate layer of copper. This can be embodied as a single layer of matte nickel with a thickness of at least 10 micrometers. Alternatively, the second intermediate layer can also be embodied as a successions of layers of bright nickel, semi-bright nickel, matte nickel, microporous nickel, and/or cracked nickel. For example, a layered structure composed of about 5 micrometers of semi-bright nickel on which a layer of matte nickel or bright nickel (depending on the desired appearance of the finished metallized surface) with a thickness of about 5 micrometers is applied has been found to be advantageous in practice. This layered structure has a high corrosion resistance due to the positive properties of semi-bright nickel. If the metallized control elements are intended for use in a highly corrosive environment, then it has proven expedient to use at least one intermediate layer of cracked nickel, particularly a succession of layers of semi-bright nickel, bright or matte nickel, and cracked nickel for the second intermediate layer.

Finally, in method step 14, a layer of a decorative metal, which can be chromium, for example, is electrodeposited on the second intermediate layer of nickel. Typical layer thicknesses of this decorative layer are between 100 nanometers and a few micrometers, and preferably at least 300 nanometers in the case of chromium.

Optionally, after removal of the base body from the electroplating, which is followed by a cleaning and a drying step (not shown in the figure), a colorizing of the metallized surface can be performed in an additional method step (not shown) by means of PVD methods. In that case, a metal layer of gold, for example, with a thickness of between 100 nanometers and a few micrometers is applied. A wide range of colors can be achieved here.

Finally, in a final method step (not shown), a layer of lacquer can be applied which, for example, can alter or improve the appearance of the metal layer that is applied on the front side and/or the corrosion resistance thereof.

As will readily be understood, the method according to the disclosure can also be carried out without individual method steps illustrated in FIG. 1. For example, if steps 8 to 10 are omitted, then this is a method variant according to step e, ii of patent claim 1—that is, the purely electrochemical deposition of at least one metal layer. Even a purely chemical deposition of at least one metal layer is conceivable.

The present disclosure is not limited to the exemplary embodiment that has been illustrated and described. Modifications are also possible within the scope of the claims, as is a combinations of the features, even if these are illustrated and described in different exemplary embodiments.

1. A method for producing a control element made of plastic with backlit imagery that is metallized on one side, particularly for a motor vehicle, the method comprising:
a. Producing a plastic base body with
i. a sub-body made of a non-electroplatable plastic A that is arranged on the rear side and
ii. an electroplatable layer of an electroplatable plastic B that is arranged on the front side,
b. applying a filler composition to at least a portion of the electroplatable layer;
c. forming the imagery through laser-lithographic processing of the applied filler composition in the regions forming the imagery;
d. removing filler composition outside of the imagery from the electroplatable layer;
e. depositing at least one metal layer on the electroplatable layer of the plastic base body through
i. chemical deposition or
ii. electrochemical deposition or
iii. chemical or physical deposition of at least one electrically conductive metal layer and subsequent electrochemical deposition of at least one additional metal layer on the electrically conductive metal layer.

2. The method as set forth in claim 1, wherein a non-electrodepositable filler composition is used.

3. The method as set forth in claim 1, wherein a filler composition is used which comprises a resist that can cure under irradiation, for example a transparent or colored photoresist.

4. The method as set forth in claim 1, wherein the filler composition is applied over the entire surface of the electroplatable layer.

5. The method as set forth in claim 1, wherein the filler composition is applied at least on those portions of the electroplatable layer in which the imagery is formed.

6. The method as set forth in claim 5, wherein the filler composition is selectively applied in a desired portion of the electroplatable layer using an applied mask.

7. The method as set forth in claim 4, wherein the filler composition is imprinted, sprayed, rolled, or brushed onto the electroplatable layer.

8. The method as set forth in claim 4, wherein the filler composition is applied to the electroplatable layer by submerging the electroplatable layer into a receiver vessel filled with the filler composition.

9. The method as set forth in claim 1, wherein the laser-lithographic processing can be carried out with a pulsed laser.

10. The method as set forth in claim 1, wherein, during the laser-lithographic processing, a focused laser beam of the laser is guided over the filler composition along a predetermined travel path.

11. The method as set forth in claim 1, wherein the plastic base body with the filler composition applied to the electroplatable layer is moved relative to a positionally fixed-focus laser beam during laser-lithographic processing.

12. The method as set forth in claim 1, wherein a laser is used whose wavelength is adapted to the wavelength necessary for initiating a photopolymerization of the filler composition.

13. The method as set forth in claim 1, wherein the radiation emanating from the laser undergoes slight absorption in the plastic A and plastic B.

14. The method as set forth in claim 1, wherein the filler composition cures at least partially in the treated locations as a result of the laser processing.

15. The method as set forth in claim 1, wherein the filler composition undergoes a secondary curing process in the laser-lithographically treated locations after processing in which the curing is completed.

16. The method as set forth in claim 1, wherein the filler composition cures completely in the treated locations as a result of the laser processing.

17. The method as set forth in claim 1, characterized in wherein the filler composition that is outside of the imagery or not cured is removed from the electroplatable layer with the aid of a solvent.

18. The method as set forth in claim 1, wherein the filler composition that is outside of the imagery or not cured is removed by means of a CO₂ spray system.

19. The method as set forth in claim 1, wherein the filler composition that is outside of the imagery or not cured is removed by pickling with a mordant.

20. The method as set forth in claim 1, wherein the edges of the laser-lithographically processed bodies are reworked after complete or partial curing thereof with a laser in order to impart a sharp contour to the imagery.

21. The method as set forth in claim 1, wherein steps b and c of the method according to claim 1 are carried out in a machine that is provided with a plurality of stations, method steps b and c each being associated with a station.

22. The method as set forth in claim 21, wherein the machine has an additional station in which step d of the method takes place.

23. The method as set forth in claim 21, wherein method step b is associated with a first station and method step c is associated with a second station.

24. The method as set forth in claim 21, wherein method step d is associated with a third station.

25. The method as set forth in claim 21, wherein method steps b, c, and optionally d are carried out with a turntable machine.

26. The method as set forth in claim 1, wherein, in order to chemically deposit the metal layer, a layer of palladium seeds is applied to the electroplatable layer.

27. The method as set forth in claim 1, wherein the applied palladium seeds are protected by a protective tin colloid layer.

28. The method as set forth in claim 1, wherein the protective tin colloid layer is removed before the chemical deposition of the metal layer.

29. The method as set forth in claim 1, wherein the surface of the electroplating layer to be electroplated is roughened, for example by chemical treatment, before the deposition of the metal layer.

30. The method as set forth in claim 1, wherein the plastic B is a transparent or translucent polyamide, ABS, or an ABS/polycarbonate blend.

31. The method as set forth in claim 1, wherein the plastic A is a polycarbonate.

32. A control element with backlightable imagery, particularly for a motor vehicle, produced by means of a method as set forth in claim 1, comprising a plastic base body with a sub-body made of a non-electroplatable plastic A that is arranged on the rear side and an electroplatable layer of an electroplatable plastic B that is arranged on the front side, the imagery being formed by a filler composition that is applied to the electroplatable layer and processed by means of laser lithography, and at least one metal layer being deposited on the electroplatable layer.

33. A machine for carrying out at least method steps b and c of the method as set forth in claim 1, comprising: a station for applying a filler composition to at least a portion of the electroplatable layer and a station for forming the imagery through laser-lithographic processing of the applied filler composition in the regions forming the imagery.

34. The machine as set forth in claim 33, wherein an additional station in which the filler composition outside of the imagery is removed from the electroplatable layer.

35. The machine as set forth in claim 33, wherein the machine is a turntable machine.
